(19) United States
(12) Patent Application Publication
(10) Pub. No.: US 2002/0021549 A1
(43) Pub. Date: Feb. 21, 2002

(54) Hybrid housing of metal board and synthetic resin

(76) Inventors: Tsutomu Kono, Kawasaki (JP); Tsuyoshi Nakagawa, Hadano (JP); Tsutomu Natsume, Mito (JP); Naozumi Hatada, Yokohama (JP); Makoto Iida, Kawasaki (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 09/884,784

(22) Filed: Jun. 19, 2001

(30) Foreign Application Priority Data
Jun. 19, 2000 (JP) 2000-187506

(51) Int. Cl. H05K 5/00

(52) U.S. Cl. 361/679

(57) ABSTRACT

The present invention provides a following housing for electronic equipment. The housing has a metal board having an adhesive layer to which one or more components are attached. In the housing, at least one of the components is formed on a surface of the metal board opposite a gate for injection molding by injecting a molding material through a through hole previously pierced in the metal board. The component has an appearance on a side of the housing opposite the gate for injection molding. Further, in the housing, at least one portion of the metal board at a side wall thereof has a convex shape.

### FIELD OF THE INVENTION

The present invention relates to a structure of a housing for electronic equipment such as a note-PC and a portable telephone, more specifically, a structure of a hybrid housing comprising a metal board and synthetic resin formed by outsert injection molding.

### BACKGROUND OF THE INVENTION

A housing for electronic equipment has a shape of a side wall, a boss for an attaching screw or the like, and it is formed by injection molding of plastics or casting of a magnesium alloy. A housing made of plastics has a problem of low rigidity, and a housing made of a magnesium alloy has a problem of high cost.

As a structure having advantages of both of the plastic housing of low cost and the metal housing of high rigidity, it is possible to consider a housing structure in which a side wall, a boss and the like are formed by outsert-molding of plastics onto a thin metal board. Recently, a trial molded part of such housing structure has been presented.

As an article to which components are attached by the outsert-molding, a housing of a note type personal computer that is described in “NIKKEI MECHANICAL” (September number, 1998, p56 to 57) is known. This is made such that a metal complex is formed on a thin aluminum board to increase the adhesiveness with the synthetic resin, so that an arbitrary component such as a rib is formed on the aluminum board by using the outsert-molding. On the other hand, as shown in JP-A-5-269787 and JP-A-7-124995 specifications, a method of using a metal base board on which an adhesive layer is formed for the purpose of joining the synthetic resin to the metal base board by the outsert-molding has also been proposed.

Furthermore, as a structure for joining a metal board and a synthetic resin material, as shown in JP-A-8-274483 specification, an example in which the electromagnetic wave shielding performance is increased by bending the metal board at an end part of side wall where the housings come into contact with each other is also proposed.

Thus, in order to realize a housing structure of low cost and high rigidity, a structure in which a plastic component such as a side wall or a boss is outsert-molded to a metal board is effective. However, if a metal board is processed to have adhesion against a plastic component for fastening the metal board and the plastic component, it becomes difficult to separate the adhered metal and plastics at the recycling time after the recovery of the electronic equipment. Furthermore, usually, if a gate for outsert injection molding is provided on a side of a component which becomes an appearance of the electronic equipment, it is necessary to perform gate processing, and there is a problem that cost becomes high.

### SUMMARY OF THE INVENTION

Therefore, it is an object of the present invention to provide a housing that has a structure of low cost and high rigidity, and is excellent in recycling-ability.

In order to attain the object, the present invention provides a following housing for electronic equipment. The housing has a metal board having an adhesive layer to which one or more components are attached. In the housing, at least one of the components is formed on a surface of the metal board opposite a gate for injection molding by injecting a molding material through a through hole previously pierced in the metal board. The component has an appearance on a side of the housing opposite the gate for injection molding. Further, in the housing, at least one portion of the metal board at a side wall thereof has a convex or concave shape.

With the structure, it is possible to decrease the cost of the gate processing for improving the appearance of the equipment, and furthermore, it becomes easier to separate two different materials by using the convex or concave shape of the metal board in the side wall as a starting point for separating the metal board and the synthetic resin component.

### BRIEF DESCRIPTION OF THE DRAWINGS

FIG. 1 is a perspective view of a hybrid housing of the invention comprising a metal board having four side walls and a synthetic resin component;

FIG. 2 is a development view of the metal board;

FIG. 3 is a view showing a cross section of a structure using the hybrid housing comprising the metal board and the synthetic resin component;

FIG. 4 is a view showing a shape of a test piece used in a bending test and a separating test;

FIG. 5 is a graph showing analysis result of relationship between a ratio of a metal board thickness to total thickness and a deformation amount;

FIG. 6 is a graph showing analysis result of relationship between the ratio of the metal board thickness to the total thickness and (1/defomation amount)/weight;

FIG. 7 is a view showing a die structure for forming a housing comprising a metal board and a synthetic resin component according to the invention;

FIG. 8 is a plan view of a housing comprising a metal board and a synthetic resin component;

FIG. 8A is a sectional view taken along line VIIIA-VIIIA in FIG. 8;

FIG. 9 is a perspective view of a hybrid housing of the invention comprising a metal board having two side walls and a synthetic resin component;

FIG. 10 is a perspective view of a hybrid housing of the invention comprising a metal board having no side wall and a synthetic resin component; and

FIG. 11 is a table showing the result of the separating test.

### DESCRIPTION OF THE PREFERRED EMBODIMENT

Embodiments of the present invention will be described hereinafter by referring to the attached drawings.

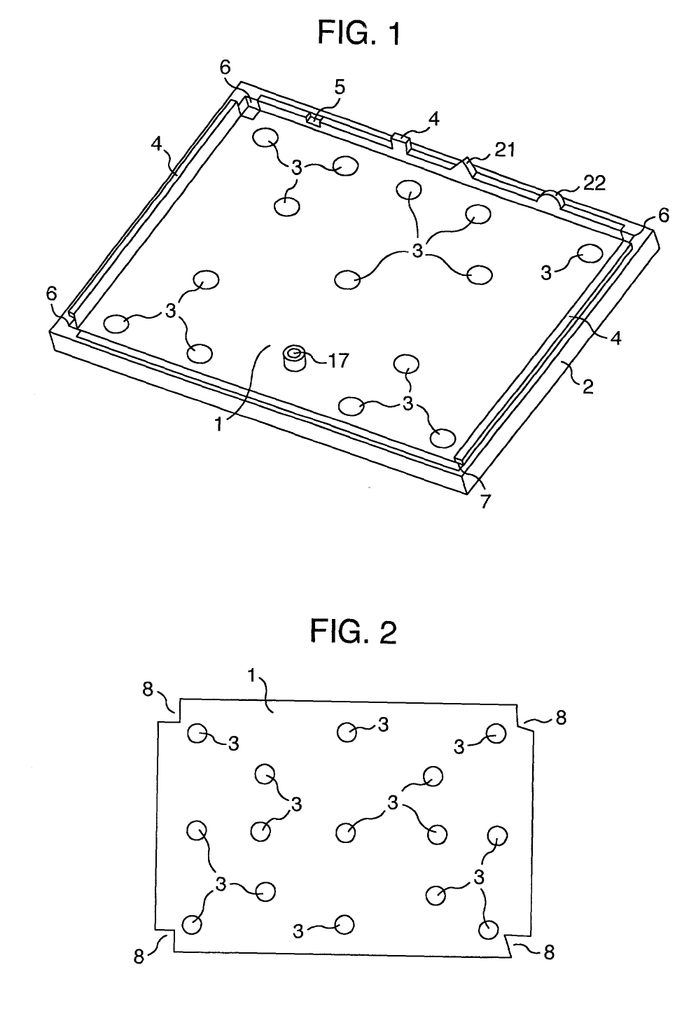

FIG. 1 shows structure of a housing for electronic equipment according to the invention in which a component is fastened to an assembly part by outsert-molding.

For the material used in the assembly part, it is possible to use metal materials such as steel, aluminum, or a magnesium alloy, thermoplastic high polymer materials such as ABS synthetic resin (acrylonitrile-butadiene-styrene), PP synthetic resin (polypropylene), PS synthetic resin (polystyrene), or PC synthetic resin (polycarbonate), thermosetting high polymer materials such as epoxy synthetic resin or phenol synthetic resin, inorganic materials such as glass, or a glass base board made by combining these metal and high polymer materials, or the like.

On the other hand, for a material for composing the component by outsert-molding, it is possible to use thermoplastic high polymer materials such as ABS synthetic resin, PP synthetic resin, PS synthetic resin, or PC resin, thermosetting high polymer materials such as epoxy synthetic resin or phenol synthetic resin, metal materials such as aluminum or a magnesium alloy, or inorganic materials such as glass or paper.

Furthermore, in the following, an example in which a metal material such as an aluminum alloy is used for the assembly part and a thermoplastic material such as ABS synthetic resin is used as the component will be described.

As shown in FIG. 1, a component 2 is joined to a metal board 1 by outsert-molding. The metal board 1 has an adhesive layer for the joining to the component 2. A development shape of the metal board 1 before performing outsert-molding is shown in FIG. 2. The developed shape of the metal board 1 has at least one or more through holes 3, and has a notch 8 of an arbitrary angle at one or more corners.

The component 2 is formed on a side of the housing that becomes an appearance side of the electronic equipment. The component 2 is formed by injecting material of the component 2 through the through holes 3 and is formed on a surface of the metal board 1 on opposite side of a gate for injection molding. At corners 6 of the housing, the metal boards 1 are in contact with each other and at a corner 7 of the housing, the metal boards 1 are not in contact with each other. The reason why the metal boards 1 are not in contact with each other at the corner 7 is that the metal board 1 should accurately be processed to have a box shape at the time of outsert-molding in order to join the metal boards 1 to each other with no clearance at the corners, so that the machining cost is increased.

Furthermore, from the viewpoint of the product recycling, it is necessary to separate different kinds of materials. For this purpose, whole of an edge portion or a part of an edge portion of the metal board 1 at the side walls is made to be a convex shape 4. Furthermore, at this moment, it is also possible that part of the metal board 1 in the side walls has a concave shape 5 for preventing the separating-off of the metal board 1 while the electronic equipment is in use. Furthermore, the convex shape 4 may be an arbitrary shape such as a triangle shape 21 or a semicircular shape 22, and the concave shape 5 may also be an arbitrary shape similarly. Furthermore, in FIG. 1, the illustration is given by a form having all of these shapes, but it is sufficient that there is at least one, and the place where it is provided is also arbitrary.

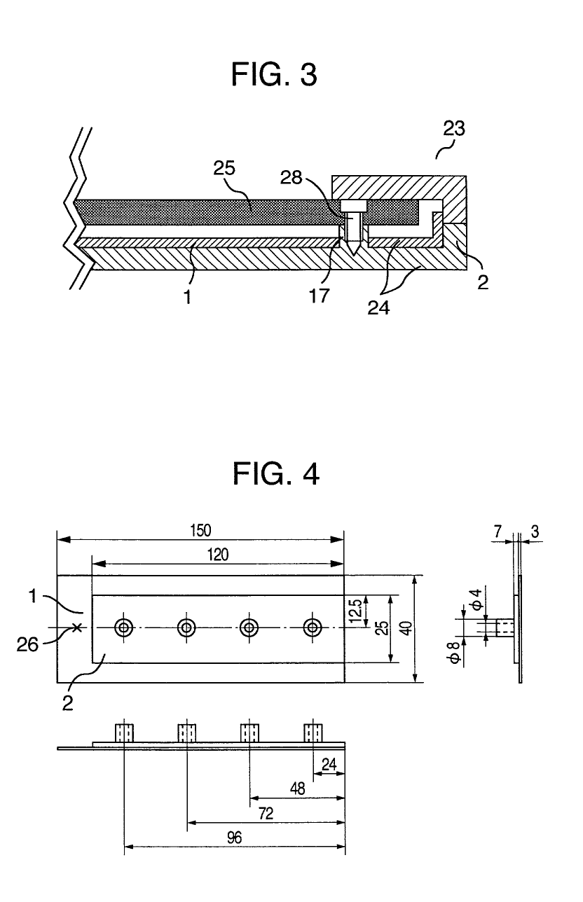

Thus, to form the convex shape 4 at the edge of the metal board 1 of the side wall, is to make the recycle easier by separating the materials by using this convex shape 4 as the starting point of separation. Furthermore, when the electronic equipment is in use, the housing 24 made of a metal board and synthetic resin and another housing 23 are combined for holding a liquid crystal base board 25 or the like, and the convex shape 4 is contained in the other housing 23 as shown in FIG. 3. Therefore, to the housing, a bending force is mainly applied. Furthermore, the other housing 23 may have an arbitrary structure of a synthetic resin housing, a metal housing of Mg or the like, or a housing 24 made of a metal board and synthetic resin.

In order to evaluate the bending force applied to the housing when the electronic equipment is in use and the anti-separating strength from the edge part of the metal board having the convex shape 4, the bending test and separating test using the test pieces shown in FIG. 4 have been performed. Furthermore, an Aluminum board has been used for the metal board 1, and a material made by filling the filler into PC synthetic resin has been used for the component 2, and the ratio of the thickness of the metal board 1 to the total thickness has been set to 5%. A nylon family adhesive has been used as the adhesive layer of the metal board 1 and the component 2. The molding condition has been set such that the temperature of the synthetic resin is 230 (° C.), and the temperature of the die is 70 (° C.), and the injection rate is 40 (cm³/s), and the dwelling is 30 (MPa). The bending test has been performed in such a way that the housing 24 made of a metal board 1 and synthetic resin component 2 is held on a jig with a span of 80 (mm), and a force is applied to the central part. Furthermore, the separating-off test has been performed in such a way that as shown in FIG. 4, a force is applied to a position 26, and a force by which the metal board 1 and the synthetic resin component 2 are separated is found.

The results of the bending test and the separating-off test are shown in FIG. 11.

It is appreciated that the flexural rigidity is improved by five times or more in comparison with that of the case where only a synthetic resin material 2 exists, but as for the separating-off, the metal board 1 and the synthetic resin component 2 are separated by a low force of 10 (N) or less. Thus, the strength has been considerably improved to the bending force applied to the housing when composing the electronic equipment or when using the electronic equipment, by adhering the metal board 1 and the synthetic resin component 2, and it has been possible to find such a characteristic that it is difficult to separate off the metal board 1 and the synthetic resin component 2. Furthermore, it has been possible to find such a characteristic that the metal board 1 and the synthetic resin component 2 can easily be separated, as for the addition of the separating-off force.

Accordingly, as shown in FIG. 1, by employing a structure in which a convex shape 4 is formed at the edge part of the metal board 1 of the housing, the separation can easily be performed by hand with using the convex shape 4 as the starting point of separation, and therefore, the recycling-ability can be improved. Furthermore, as another material fractionating method, such a method where the fractionating is performed by applying a bending force to the housing to break the material can be considered, but as shown in FIG. 11, the housing 24 made of a metal board 1 and a synthetic resin component 2 has a large flexure modulus, and breaking is not easy. In addition to that, for separating the materials, the metal board 1 and the synthetic resin component 2 are separated after a bending force has been applied to break the materials, and therefore, the number of the material fractionating steps becomes larger than that of the case where the separating is performed by using the convex shape 4 as the starting point of separation, and the recycling cost also becomes higher.

Next, in order to determine a proper value of the ratio of thickness between the metal board 1 and the synthetic resin component 2, a bending test has been performed. As the test pieces, flat boards of 300 mm (width)×240 mm (depth)×1.4 mm (thickness) have been used, in which the ratio of thickness between the metal board 1 and the synthetic resin component 2 is changed. Furthermore, as restricting condition, such a condition that the displacements in a direction of height at four places apart from the four corners by 30 mm (width) and 30 mm (depth) are restricted, and that a force of 19.6 N is applied to the center has been used, and a deformation amount in the height direction of a central part is evaluated. Furthermore, as the metal board 1, an Aluminum board has been used, and as the synthetic resin component 2, ABS synthetic resin and PC synthetic resin filled with filler have been used. Furthermore, as for the flexure modulus of the synthetic resin material, ABS synthetic resin has 2.5 GPa and PC synthetic resin filled with filler has 7.9 GPa, and by using these materials whose flexure modulus are considerably different, the effect given to the strength by the difference of the flexure modulus between the metal board 1 and the synthetic resin component 2 has been evaluated.

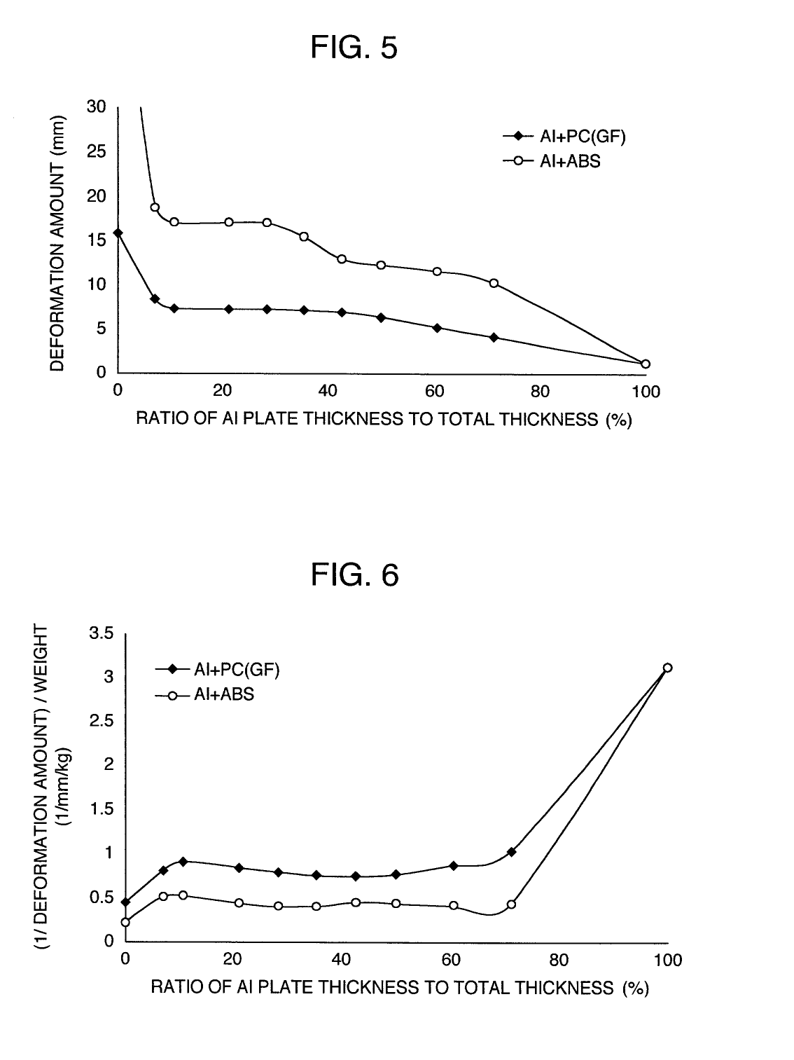

The result thereof is shown in FIG. 5. According to this, if ABS synthetic resin with a low flexure modulus is used, deformation amount becomes larger than that of the case where PC synthetic resin filled with filler is used, but regardless of which synthetic resin material is used, if the ratio of the thickness of the metal board to the total thickness is about 10% or less, the deformation amount becomes considerably smaller as the thickness of the metal board becomes larger, and a considerable improved effect of the rigidity can be confirmed. Furthermore, it is understood that if the ratio of the thickness of the metal board to the total thickness is in the range of about 15% to about 30%, the deformation amount becomes an approximately constant value, and even if the thickness of the metal board is increased, the rigidity does not change, and only the weight is increased.

Furthermore, the difficulty of deformation per weight has been evaluated by using the value of (1/deformation amount)/weight that is made by dividing the reciprocal of this deformation amount shown in FIG. 5 by the weight. The result thereof is shown in FIG. 6. It can be understood from this that the value of (1/deformation amount)/weight becomes the maximum value when the ratio of the thickness of the metal board to the total thickness is about 8% to about 12%, both in the case where ABS synthetic resin is used as the synthetic resin material and in the case where PC synthetic resin filled with carbon filler is used. Accordingly, in order to realize a housing structure of light weight and high rigidity, it is preferable that the ratio of the thickness of the metal board to the total thickness is about 8% to about 12%. Furthermore, in the case where the ratio of the thickness of the metal board to the total thickness is 5% or less, an effect of improvement of rigidity is also observed. Therefore, a housing structure of the ratio of about 1% to about 5% can also be used as a light-weight housing, though the strength is lower than that of the above described housing of the optimum thickness ratio of about 8% to about 12%. On the other hand, in the case where the ratio of the thickness of the metal board to the total thickness is about 15% to about 30%, no effect of improvement of rigidity is observed. However, in the case where the ratio is 30% or more, the strength becomes larger though the weight becomes larger than that of the housing of the optimum thickness ratio of about 8% to about 12%. Therefore, the housing structure whose ratio of the thickness of the metal board to the total thickness is 30% or more and 50% or less can also be used as a housing with high strength. Furthermore, in the case where the ratio of the thickness of the metal board to the total thickness is 50% or more, the synthetic resin thickness becomes extremely thin, and the moldability becomes worse, which is not proper.

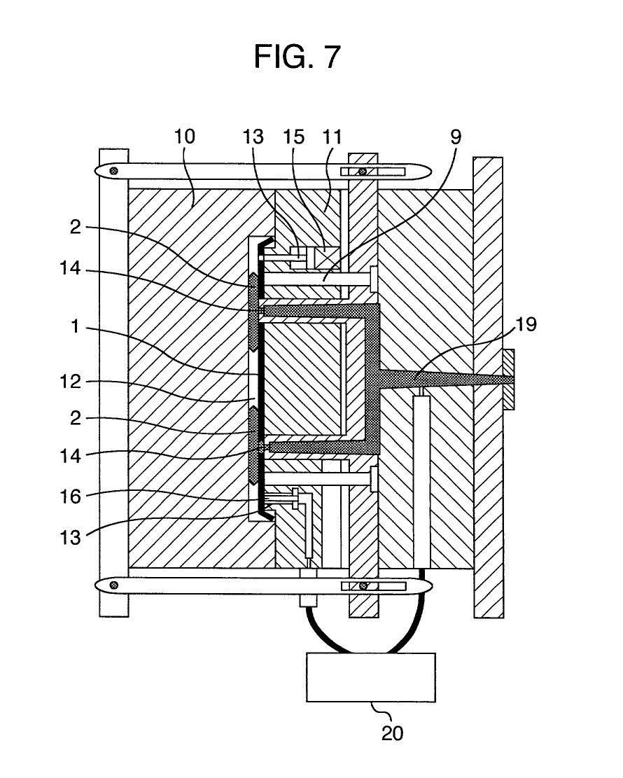

A structure of holding the metal board 1 to a die at the time of outsert-molding is shown in FIG. 7. The outsert-molding steps using the die are made as follows. An eject pin 9 or a dummy pin 13 is protruded from a face of a fixed die 11 into through holes of the metal board 1 to locate the metal board 1 in a cavity 12. Thereafter, by applying vacuum-evacuation to the metal board 1 from a through hole 16 pierced in the center of the dummy pin 13 or a clearance of fitting of the eject pin 9, the metal board 1 is fixed to the fixed die 11. Then, synthetic resin material for the component 2 is injected into the cavity 12. The dummy pin 13 may also have such a structure that it is moved into the fixed die 11 by a hydraulic cylinder 15 or the like after the positioning and fixing of the metal board 1 with respect to the fixed die 11 by the vacuum-evacuation have been finished.

At this moment, the synthetic resin for the component 2 injected in the die cavity 12 from a gate 14 is flowed through the through hole 3 of the metal board 1 to adhere on a surface of the metal board 1 opposite side of the gate, and bend an edge of the metal board 1 to form a side wall on account of injection pressure.

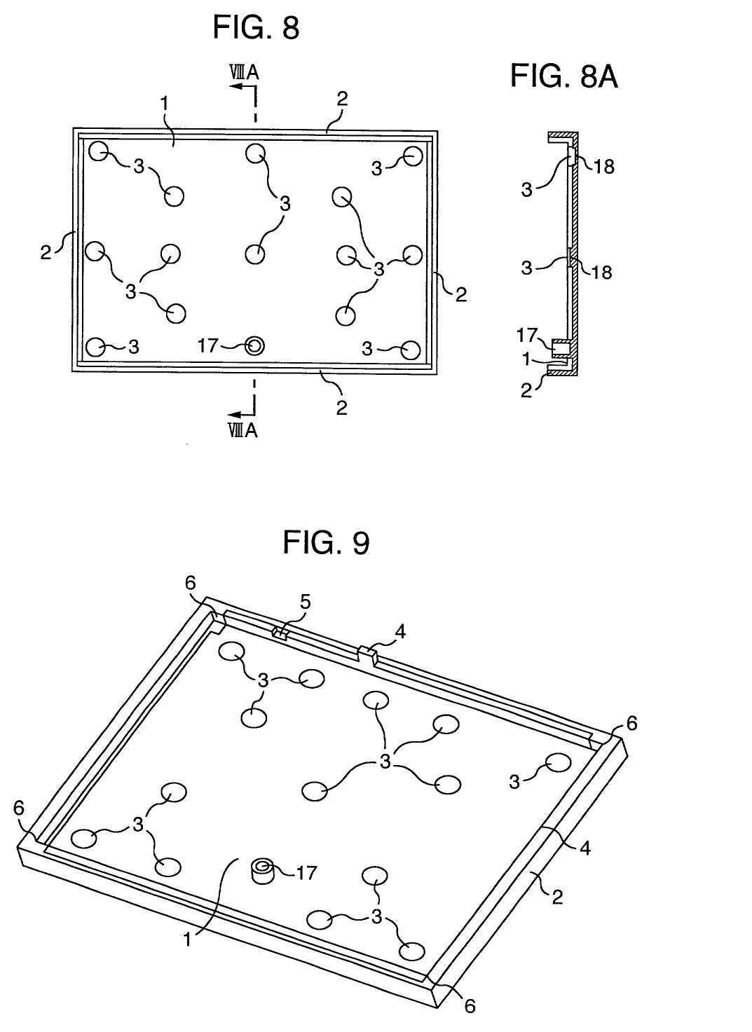

This housing structure that has been subjected to the outsert-molding by using the eject pin 9 or dummy pin 13 performing the positioning is shown in FIG. 8. When the eject pin 9 or dummy pin 13 is extended into the cavity 12 over the metal board 1, a concave 18 is formed in the component 2 and when the pin 9 or 3 is extended into the cavity 12 not over the metal board 1, a convex 18 is formed in the component 2 as shown in FIG. 8A. The concave or convex 18 of the component 2 at the through holes 3 may take any shape. Furthermore, as shown in FIGS. 8 and 8A, a boss 17 can be formed at the position of the through hole 3. The boss 17 can also be formed at a place other than the through hole 3 by passing through the metal board 1 by the injection pressure of the synthetic resin.

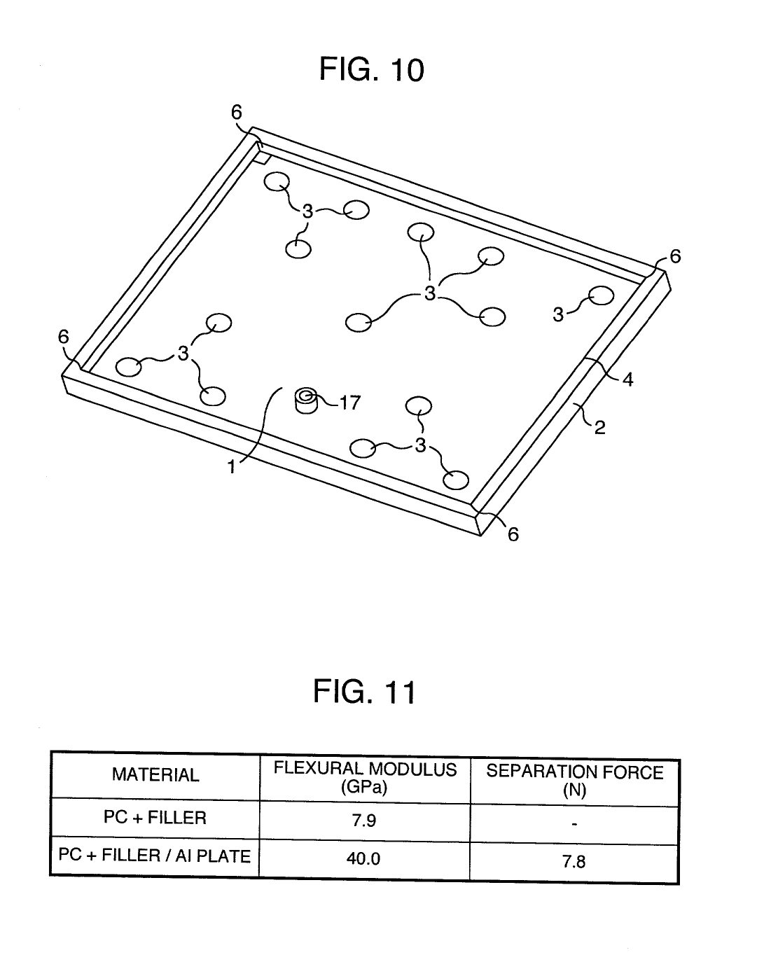

In the above-described housing, the metal board 1 is outsert-molded at four side walls, but the present invention is not limited to this embodiment. It is also possible to have a structure in which the metal board 1 is outsert-molded only at two side walls as shown in FIG. 9, or a structure in which the metal board 1 is not outsert-molded at any side wall as shown in FIG. 10. Furthermore, in the case where the structure shown in FIG. 10 is used, there is no convex shape of the metal board at the side wall, and therefore, it is necessary to perform the material fractionating after the breaking of the housing.

Hereinbefore, a method of joining components to a metal board with a flat shape has been described, but the present invention is not limited to this, and it is also possible to join components to a metal board with any shape including a curved surface by the outsert-molding. Furthermore, in the above description, a structure in which an adhesive layer is formed on a metal board to join the metal board to the synthetic resin component has been shown. However, the present invention is not limited to this. It is also possible to join the synthetic resin component without forming an adhesive layer on the metal board, by using a thermosetting material having adhesive properties with metals such as epoxy synthetic resin.

As described above, the description has been given by taking an electronic equipment housing as one example, but by using the manufacturing method according to the present invention, processed goods other than the electronic equipment housing can also be manufactured effectively, if they have a structure where components are attached.

Based on the electronic equipment housing according to the present invention, it is possible to form a housing with a structure that is of low cost and high rigidity, and furthermore, is excellent in recycling-ability.

What is claimed is:

1. A housing for electronic equipment comprising:
a metal base board having at least one through holes;
one or more components that are joined to the metal base board by outsert-molding; and
one or more side walls in which said metal base board and said one or more components are joined,
wherein at least one part of a terminal part of said metal base board at one or more side walls is formed in a convex shape which is not joined to said components.

2. A housing for electronic equipment comprising:
a metal base board;
one or more components that are joined to the metal base board by outsert-molding; and
one or more side walls in which said metal base board and said one or more components are joined,
wherein at least one part of a terminal part of said metal base board at one or more side walls is formed in a concave shape.

3. A housing for electronic equipment comprising:
a metal base board; and
one or more components that are joined to the metal base board by outsert-molding; and
two or more side walls in which at least one part of said metal base board is joined with said components,
wherein at at least one corner formed by two of said two or more side walls, said metal base boards forming said two side walls are not partially or entirely in contact with each other.

4. A housing for electronic equipment comprising:
a metal base board;
one or more components that are joined to the metal base board by outsert-molding; and
a side wall,
wherein said components are joined to whole of one surface of said metal base board except for at least the side wall, and a ratio of thickness of said metal base board to a total thickness of the housing is in a range of 1% to 5%.

5. A housing for electronic equipment comprising:
a metal base board;
one or more components that are joined to the metal base board by outsert-molding; and
a side wall,
wherein said components are joined to whole of one surface of said metal base board except for at least the side wall, and a ratio of thickness of said metal base board to total thickness of the housing is in a range of 8% to 12%.

6. A housing for electronic equipment comprising:
a metal base board;
one or more components that are joined to the metal base board by outsert-molding; and
a side wall,
wherein said components are joined to whole of one surface of said metal base board except for at least the side wall, and a ratio of thickness of said metal base board to total thickness of the housing is in a range of 30% to 50%.

7. The housing for electronic equipment according to claim 1, wherein a development shape of said metal base board has at least one through hole, and has a notch of an arbitrary angle at one or more corners of the development shape.

8. The housing for electronic equipment according to claim 6, wherein a development shape of said metal base board has at least one through hole, and has a notch of an arbitrary angle at one or more corners of the development shape.

9. The housing for electronic equipment according to claim 1, wherein on a surface of said component attached on said metal base board, said component is formed in a concave shape at at least one of portions corresponding to said through holes of said metal base board.

10. A manufacturing method of a housing for electronic equipment including a metal base board and one or more components that are joined to the metal base board by outsert-molding, comprising the steps of:
forming said components on a surface of said metal base board opposite to a gate for the outsert-molding by synthetic resin injection from the gate provided at a position where synthetic resin can be injected through at least one through hole of said base board; and
bending and processing side walls of the housing by pressure of injection of synthetic resin.

11. A manufacturing method of a housing for electronic equipment including a metal base board and one or more components that are joined to the metal base board by outsert-molding,
wherein as a method of fixing said metal base board to a die when forming said components on a surface of the metal base board opposite to a gate for the outsert-molding by synthetic resin injection from the gate provided at a position where synthetic resin can be injected through at least one through hole of said metal base board, a positioning pin is provided to at least one of said through holes.

12. The manufacturing method of a housing for electronic equipment according to claim 11,
wherein vacuum-pull is used for fixing said base board onto the die.

13. Electronic equipment comprising a housing for electronic equipment according to claim 1.
